(19) United States
(12) Patent Application Publication
(10) Pub. No.: US 2026/0026012 A1
(43) Pub. Date: Jan. 22, 2026

(54) SEMICONDUCTOR MEMORY DEVICE AND ELECTRONIC SYSTEM INCLUDING THE SAME

(71) Applicant: Samsung Electronics Co., Ltd., Suwon-si (KR)

(72) Inventors: Junghoon PARK, Suwon-si (KR); Joo-Heon KANG, Suwon-si (KR)

(73) Assignee: Samsung Electronics Co., Ltd., Suwon-si (KR)

(21) Appl. No.: 19/014,930

(22) Filed: Jan. 9, 2025

(30) Foreign Application Priority Data
Jul. 19, 2024 (KR) 10-2024-0095593

(51) Int. Cl. H10B 63/00

(52) U.S. Cl. CPC H10B 63/845; H10B 63/34

(57) ABSTRACT

A semiconductor memory device with improved electrical characteristics and reliability is provided. The semiconductor memory device may include a substrate, a mold structure including a plurality of mold insulating layers and a plurality of gate electrodes alternately stacked on the substrate in a first direction, and a channel structure formed through the mold structure and extending in the first direction, in which the channel structure includes a channel layer and an ion conductive layer disposed between the plurality of gate electrodes and the channel layer.

### CROSS-REFERENCE TO RELATED APPLICATION

This application claims priority to Korean Patent Application No. 10-2024-0095593, filed in the Korean Intellectual Property Office on Jul. 19, 2024, the entire contents of which are hereby incorporated by reference.

### BACKGROUND

Some example embodiments relate to a semiconductor memory device and/or an electronic system including the same.

There is a desire for a semiconductor memory device capable of storing high-capacity data in an electronic system that requires data storage. Accordingly, ways to increase the data storage capacity of the semiconductor memory devices are being studied. For example, as one of the methods for increasing the data storage capacity of the semiconductor device, a semiconductor device has been proposed, which includes three-dimensional arrangement of memory cells instead of two-dimensional arrangement of memory cells.

### SUMMARY

In order to solve or improve upon one or more problems (e.g., the problems described above and/or other problems not explicitly described herein), some example embodiments provide a semiconductor memory device with improved electrical characteristics and/or reliability.

Alternatively or additionally, in order to solve or improve upon one or more problems (e.g., the problems described above and/or other problems not explicitly described herein), some example embodiments provide an electronic system with improved electrical characteristics and/or reliability.

According to some example embodiments, a semiconductor memory device may include a substrate, a mold structure including a plurality of mold insulating layers and a plurality of gate electrodes alternately stacked on the substrate in a first direction, and a channel structure through the mold structure and extending in the first direction, in which the channel structure may include a channel layer, and an ion conductive layer between the plurality of gate electrodes and the channel layer.

Alternatively or additionally according to some example embodiments, a semiconductor memory device may include a substrate, a mold structure including a plurality of mold insulating layers and a plurality of gate electrodes alternately stacked on the substrate in a first direction, and a channel structure through the mold structure and extending in the first direction, in which the channel structure may include an ion storage layer, an ion conductive layer, a barrier layer, and a channel layer sequentially on the plurality of gate electrodes.

Alternatively or additionally according to some example embodiments, an electronic system may include a main substrate, a semiconductor memory device on the main substrate and including a peripheral circuit structure and a cell structure stacked on the peripheral circuit structure, and a controller on the main substrate, which is electrically connected to the semiconductor memory device. The cell structure may include a mold structure including a plurality of mold insulating layers and a plurality of gate electrodes alternately stacked on the substrate in a first direction, and a channel structure through the mold structure and extending in the first direction, in which the channel structure may include a channel layer, and an ion conductive layer between the plurality of gate electrodes and the channel layer.

According to some example embodiments, the semiconductor memory device may be operated at a low voltage such that a gate length and/or an inter-gate length may be reduced.

Accordingly, the integration density and/or the electrical characteristics of the semiconductor device may be improved.

Alternatively or additionally according to some example embodiments, the resistance switching layer is disposed inside the channel structure to reduce the frequency of active ions directly penetrating the channel layer during a read operation, thereby delaying the deterioration of the channel layer and/or improving the electrical characteristics of the semiconductor memory device.

### BRIEF DESCRIPTION OF THE DRAWINGS

The above and other objects, features and advantages of the present disclosure will become more apparent to those of ordinary skill in the art by describing in detail some example embodiments thereof with reference to the accompanying drawings, in which:

FIG. 1 is a plan view provided to explain a semiconductor memory device according to some example embodiments;

FIG. 2 is a cross-sectional view taken along line A-A of FIG. 1;

FIG. 3 is an enlarged view provided to explain a region Q1 of FIG. 2;

FIG. 4 is a cross-sectional view taken along line CL1 of FIG. 3;

FIG. 5 is a diagram provided to explain a semiconductor memory device according to some example embodiments;

FIG. 6 is a cross-sectional view taken along line CL2 of FIG. 5;

FIG. 7 is a diagram provided to explain a semiconductor memory device according to some example embodiments;

FIG. 8 is a diagram provided to explain a semiconductor memory device according to some example embodiments;

FIG. 9 is a diagram provided to explain a semiconductor memory device according to some example embodiments;

FIG. 10 is a diagram provided to explain a semiconductor memory device according to some example embodiments;

FIG. 11 is a diagram provided to explain a semiconductor memory device according to some example embodiments;

FIG. 12 is a diagram provided to explain a semiconductor memory device according to some example embodiments;

FIG. 13 is a diagram provided to explain a semiconductor memory device according to some example embodiments;

FIG. 14 is a diagram provided to explain a semiconductor memory device according to some example embodiments;

FIG. 15 is a diagram provided to explain a semiconductor memory device according to some example embodiments;

FIG. 16 is a block diagram provided as an example to explain an electronic system according to some example embodiments;

FIG. 17 is an example perspective view illustrating an electronic system including a semiconductor memory device according to some example embodiments; and

FIG. 18 is a schematic cross-sectional view taken along line V-V of FIG. 17.

### DETAILED DESCRIPTION

Hereinafter, a semiconductor memory device, an electronic system, and/or a method for manufacturing the same according to some example embodiments will be described in detail with reference to the drawings.

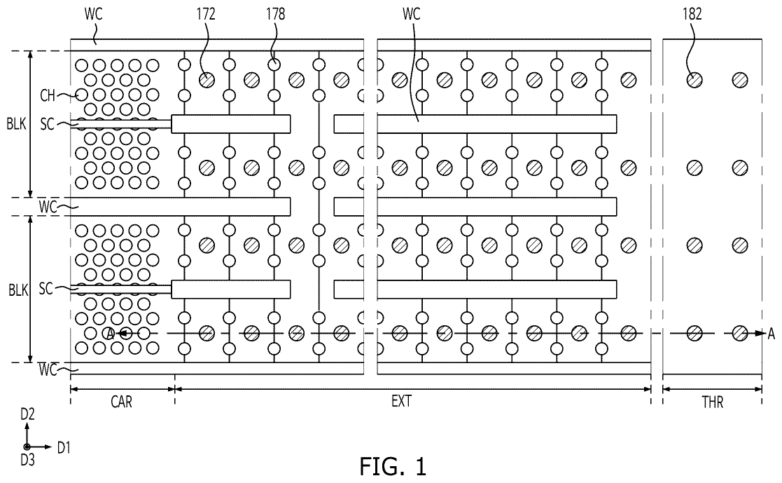

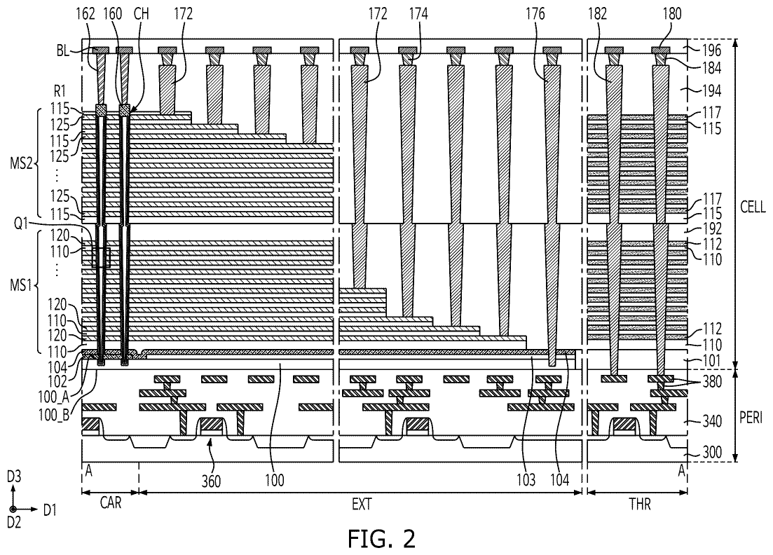

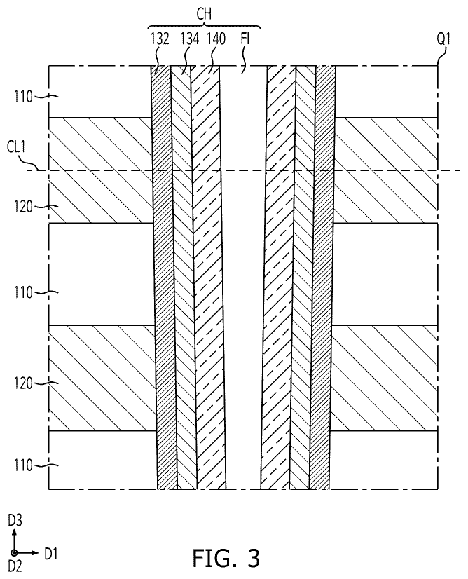

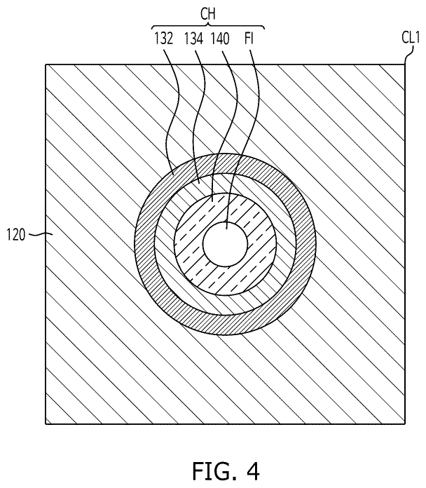

FIG. 1 is a plan view provided to explain a semiconductor memory device according to some example embodiments. FIG. 2 is a cross-sectional view taken along line A-A of FIG. 1. FIG. 3 is an enlarged view provided to explain the region Q1 of FIG. 2. FIG. 4 is a cross-sectional view taken along line CLI of FIG. 3.

Referring to FIGS. 1 to 4, a semiconductor memory device according to some example embodiments may include a cell structure CELL and a peripheral circuit structure PERI.

The cell structure CELL may include a cell substrate 100, a first mold structure MS1, a second mold structure MS2, a channel structure CH, a channel pad 160, a bit line BL, a word line contact 172, a source contact 176, a through via 182, and a first wiring structure 180, among others.

The cell substrate 100 may include, e.g., be partitioned into, a cell array region CAR, an extension region EXT, and a through region THR.

A memory cell array including a plurality of memory cells may be formed on the cell array region CAR. The channel structure CH, the first mold structure MS1, the second mold structure MS2, the bit line BL, etc., may be disposed on the cell array region CAR.

The extended region EXT may be disposed around the cell array region CAR. For example, the extension region EXT may surround the cell array region CAR. The word line contact 172, a support structure 178, etc. may be disposed on the extension region EXT.

The through region THR may be disposed outside the extension region EXT. For example, the through region THR may be disposed on one side of the extension region EXT, but aspects are not limited thereto. The through via 182 may be disposed in the through region THR.

For example, the cell substrate 100 may be or may include a semiconductor substrate such as one or more of a silicon substrate, a germanium substrate, or a silicon-germanium substrate. Alternatively or additionally, the cell substrate 100 may include a silicon-on-insulator (SOI) substrate, a germanium-on-insulator (GOI) substrate, etc. In some example embodiments, the cell substrate 100 may include polysilicon (poly Si).

The cell substrate 100 may include a first side 100_A and a second side 100_B opposite the first side 100_A. The first side 100_A of the cell substrate 100 may be a side upon which the first mold structure MS1 and the channel structure CH are disposed. The first side 100_A of the cell substrate 100 may be referred to as a front side of the cell substrate 100. The second side 100_B of the cell substrate 100 may be referred to as a back side of the cell substrate 100.

The first mold structure MS1 may be formed on the first side 100_A of the cell substrate 100. The first mold structure MS1 may include a plurality of first mold insulating layers 110 and a plurality of first gate electrodes 120 that are alternately stacked in a third direction D3. Each of a first mold insulating layer 110 and each of the first gate electrodes 120 may have a layered structure extending parallel to the first side 100_A of the cell substrate 100. The first gate electrodes 120 may be spaced apart from each other by the first mold insulating layer 110 and sequentially stacked on the cell substrate 100.

The second mold structure MS2 may be formed on the first mold structure MS1. The second mold structure MS2 may include a plurality of second mold insulating layers 115 and a plurality of second gate electrodes 125 that are alternately stacked. Each of the second mold insulating layer 115 and each of the second gate electrodes 125 may have a layered structure extending parallel to the first side 100_A of the cell substrate 100. The second gate electrodes 125 may be spaced apart from each other by the second mold insulating layer 115 and sequentially stacked on the first mold structure MS1.

A height, e.g., a height in the third direct D3, of the first mold structure MS1 may be the same as, or different from (e.g., greater than or less than) a heigh of the second mold structure MS2. Alternatively or additionally, a number of first gate electrodes 120 and/or a number of first mold insulating layers 110 may be the same as, or different from (e.g., greater than or less than) a number of second gate electrodes 125 and/or a number of second mold insulating layers 115.

In some example embodiments, some of the plurality of first gate electrodes 120 may be used as a ground select line GSL and an erase control line ECL of the semiconductor memory device. For example, a first gate electrode 120 from among the plurality of first gate electrodes 120 that is adjacent to source structures 102 and 104 may be used as the erase control line ECL. The erase control line ECL may be used as a gate electrode of an erase transistor. The erase transistor may generate a gate induced drain leakage (GIDL) current to perform an erase operation on a plurality of memory cell transistors. A first gate electrode 120 adjacent to the erase control line ECL may be provided as the ground select line GSL. However, example embodiments are not limited thereto. The arrangement and/or the number of the erase control lines ECL and the ground select lines GSL may vary.

In some example embodiments, some of the plurality of second gate electrodes 125 may be provided as a string select line SSL of the semiconductor memory device. For example, a second gate electrode 125 of the plurality of second gate electrodes 125 that is adjacent to the bit line BL may be provided as the string select line SSL. However, example embodiments are not limited thereto. The arrangement and number of string select lines SL may vary.

Each of the first mold insulating layers 110 and the second mold insulating layers 115 may include an insulating material. For example, each of the first mold insulating layers 110 and the second mold insulating layers 115 may include at least one of silicon oxide, silicon nitride, and silicon oxynitride, but example embodiments are not limited thereto.

Each of the first gate electrodes 120 and the second gate electrodes 125 may include a conductive material. For example, each of the first gate electrodes 120 and the second gate electrodes 125 may include metals such as at least one of a titanium-gold alloy (Au—Ti), tungsten (W), aluminum (Al), cobalt (Co), nickel (Ni), copper (Cu), silver (Ag), palladium (Pd), and a semiconductor material such as gold and/or germanium and/or silicon, but example embodiments are not limited thereto.

Although FIG. 2 illustrates that the number of mold structures MS1 and MS2 is two, example embodiments are not limited thereto. For example, the number of mold structures MS1 and MS2 may be three or four or more.

The channel structure CH may be formed through each of the first mold structure MS1 and the second mold structure MS2. For example, the channel structure CH may be formed through and intersect each of the plurality of first mold insulating layers 110 and the plurality of first gate electrodes 120. The channel structure CH may be formed through and intersect each of the plurality of second mold insulating layers 115 and the plurality of second gate electrodes 125. The channel structure CH may extend in the third direction D3. The channel structure CH may have a pillar shape (e.g., a cylindrical shape) extending in the third direction D3.

The channel structure CH may have a bent portion between the first mold structure MS1 and the second mold structure MS2. In some example embodiments, the cross section of the channel structure CH disposed in the first mold structure MS1 may have an inclined or tapered side surface such that a width thereof is progressively narrowed toward the cell substrate 100. However, example embodiments are not limited thereto.

In some example embodiments, the channel structures CH may be arranged in a zigzag form. For example, as illustrated in FIG. 1, the channel structures CH may be disposed to cross each other in first and second directions D1 and D2. The channel structures CH disposed in the zigzag form may further improve the integration density of the semiconductor memory device. In some example embodiments, in a plan view the channel structures CH may be arranged in a honeycomb form, e.g., at vertices of a hexagonal lattice such as of a regular hexagonal lattice.

The channel structure CH may include an ion storage layer 132, an ion conductive layer 134, a channel layer 140, and a filling insulating layer FI sequentially disposed on the plurality of first gate electrodes 120. For example, a channel hole extending in the third direction D3 and formed through the mold structures MS1 and MS2 may be formed. The ion storage layer 132, the ion conductive layer 134, the channel layer 140, and the filling insulating layer FI may be sequentially stacked in the channel hole.

The ion storage layer 132 may be disposed between the plurality of first gate electrodes 120 and the ion conductive layer 134. For example, an inner surface of the ion storage layer 132 may be in contact with (e.g., in direct contact with) an outer surface of the ion conductive layer 134, and an outer surface of the ion storage layer 132 may be in contact with (e.g., in direct contact with) the plurality of first gate electrodes 120. The outer surface of the ion storage layer 132 may be in contact with the mold structures MS1 and MS2. In some example embodiments, the ion storage layer 132 may be disposed at an outermost side of the channel structure CH. For example, as illustrated in FIG. 4, the ion storage layer 132 may have a shape of a hollow tube (e.g., cylindrical shape) and may surround the ion conductive layer 134.

The ion storage layer 132 may store active ions. The active ions stored in the ion storage layer 132 may include one or more of oxygen ions, lithium ions, or hydrogen ions (e.g., protons). In some example embodiments, the active ions stored in the ion storage layer 132 may move to the channel layer 140 through the ion conductive layer 134. In addition, the active ions moved to the channel layer 140 may move to the ion storage layer 132 through the ion conductive layer 134.

In some example embodiments, the ion storage layer 132 may include an oxygen ion storage material. The oxygen ion storage material may include at least one of metal-oxide, transition-metal oxide (TMO), or metal-insulator transition material. For example, the ion storage layer 132 may include WOx, GdOx, MoOy, Ta2O5, Al2O3, TiOx, HfOx, SiOx, or a combination thereof. Here, x may represent a natural number of 1 or more. This may be equally applied in the description of the material of the components of the present disclosure. For example, in the following description of the material of the components, n, x, and y may represent natural numbers of 1 or more, and may be the same as, or different from, one another.

In some example embodiments, the ion storage layer 132 may include a lithium ion storage material. The lithium ion storage material may include at least one of crystalline silicon, amorphous silicon, or lithium ion oxide. For example, the ion storage layer 132 may include Si, LixTiO2, α-Si, or a combination thereof.

In some example embodiments, the ion storage layer 132 may include a hydrogen ion storage material. The hydrogen ion storage material may include at least one of a metal, a metal-based catalyst, silicon, or a conductive polymer. For example, the ion storage layer 132 may include Pd, Ti, Zr, Hf, V, Nb, Ta, Ni, Pt, TiH2, ZrH2, VH2, NbH, NiH, PdHx, Si, PEDOT:PSS, p(g2T-TT), or a combination thereof.

The ion conductive layer 134 may be disposed between the ion storage layer 132 and the channel layer 140. For example, an inner surface of the ion conductive layer 134 may be in contact with an outer surface of the channel layer 140, and the outer surface of the ion conductive layer 134 may be in contact with the ion storage layer 132. The ion conductive layer 134 may have a shape of a hollow tube (e.g., a cylindrical shape). For example, as illustrated in FIG. 4, the ion conductive layer 134 may surround the channel layer 140.

The ion conductive layer 134 may include an electrolyte through which active ions may be movable between the ion storage layer 132 and the channel layer 140. The active ion may include one or more of oxygen ions, lithium ions, hydrogen ions, or metal ions, but is not limited thereto. In some example embodiments, the ions may be cationic (having at least one fewer electron than proton) and/or may be anionic (having at least one more electron than proton); example embodiments are not limited thereto.

In some example embodiments, the ion conductive layer 134 may include an electrolyte through which oxygen ions may be movable between the ion storage layer 132 and the channel layer 140. For example, the ion conductive layer 134 may include HfOx (HfO2), ZrOx, Ta2O5, Yttria Stabilized Zirconia (YSZ), or a combination thereof.

In some example embodiments, the ion conductive layer 134 may include an electrolyte through which lithium ions are movable between the ion storage layer 132 and the channel layer 140. For example, the ion conductive layer 134 may include LiPON, LiClO4/PEO, Li3PO4, Li3POxSex, or a combination of thereof.

In some example embodiments, the ion conductive layer 134 may include an electrolyte through which hydrogen ions are movable between the ion storage layer 132 and the channel layer 140. The ion conductive layer 134 may include phosphorus silicate glass (PSG), Nafion, EMIM-TFSI, EMIM; TFSI PVDF-HFP, SiO2+ionic liquid, Hexagonal Boron Nitride (hBN), H2SO4-PVA, or a combination thereof.

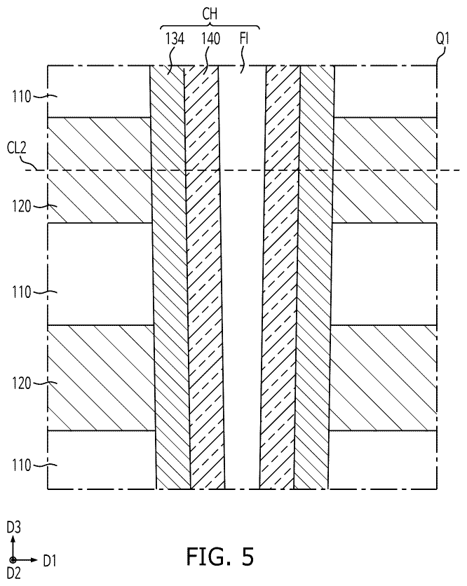

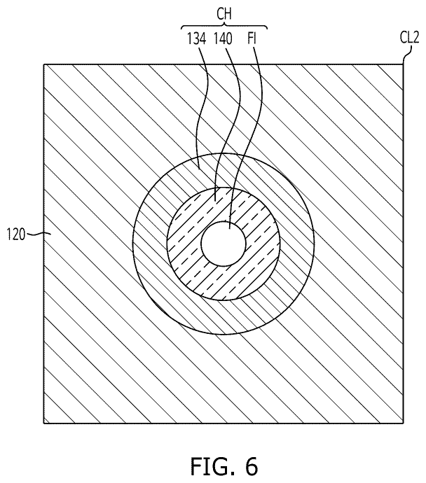

In some example embodiments, the ion conductive layer 134 may include an electrolyte through which metal ions may be movable. Detailed description of the material of the ion conductive layer 134 when the active ion is a metal ion will be described in detail with reference to FIGS. 5 and 6.

The material for the ion conductive layer 134 is not limited to the examples described above, and the ion conductive layer 134 may include various electrolytes through which each active ion can move, e.g., can easily move within the medium.

The channel layer 140 may be disposed between the ion conductive layer 134 and the filling insulating layer FI. For example, an inner surface of the channel layer 140 may be connected to an outer surface of the filling insulating layer FI, and an outer surface of the channel layer 140 may be connected to the ion conductive layer 134. The channel layer 140 may have a shape of a hollow tube (e.g., a cylindrical shape). For example, as illustrated in FIG. 4, the channel layer 140 may surround the filling insulating layer FI.

If a voltage is applied to one gate electrode selected from among the plurality of first gate electrodes 120, the conductivity of the channel layer 140 may be changed by the active ions moving through a partial region of the ion conductive layer 134 associated with the selected gate electrode, and accordingly, the threshold voltage Vth may be changed.

The channel layer 140 may include a material that changes in conductivity with the movement of the active ions from the ion storage layer 132. In some example embodiments, the channel layer 140 may include a material that changes in conductivity with the oxygen ions. For example, the channel layer 140 may include WOx, Indium Gallium Zinc Oxide (IGZO), Indium Zinc Oxide (IZO), ZnO, Zinc Tin Oxide (ZTO), InO, Praseodymium Calcium Manganese Oxide (PCMO), TiO2, doped or undoped polycrystalline silicon, doped or undoped crystalline silicon, etc.

In some example embodiments, the channel layer 140 may include a material that changes in conductivity with the lithium ions. For example, the channel layer 140 may include LixCoO2, LixTiO2, IGZO, WOx, α-MoO3, etc.

In some example embodiments, the channel layer 140 may include a material that changes in conductivity with hydrogen ions. For example, the channel layer 140 may include one or more of WOx, α-MoO3, NdNiO3, PEDOT: PSS/PEI, PEDOT:PSS, p(g2T-TT), (Mxene/TaPa)n, etc.

In some example embodiments, the channel layer 140 may include a material that changes in conductivity with metal ions. Detailed description of the material of the channel layer 140 when the active ion is a metal ion will be described in detail with reference to FIGS. 5 and 6.

The material for the channel layer 140 is not limited to the example described above, and the channel layer 140 may include various materials through which each active ion is easily moved within the medium and which change in conductivity with the active ions.

The semiconductor memory device may be operated at a low voltage (e.g., 10 V or less) by components of the channel structure CH such that a gate length (Lg) and/or inter-gate space (Ls) may be reduced. Accordingly, the integration density and/or the electrical characteristics of the semiconductor device may be improved.

The filling insulating layer FI may be disposed to fill the inside of the channel layer 140. For example, the filling insulating layer FI may include an insulating material such as silicon oxide, but example embodiments are not limited thereto.

The channel pad 160 may be disposed on the channel structure CH. The channel pad 160 may be disposed on an upper portion of the channel structure CH and be electrically connected to the channel layer 140. For example, the channel pad 160 may include polysilicon doped with an impurity, but is not limited thereto. Alternatively or additionally, the channel pad 160 may be in contact with a bit line contact 162 and electrically connected to the bit line contact 162.

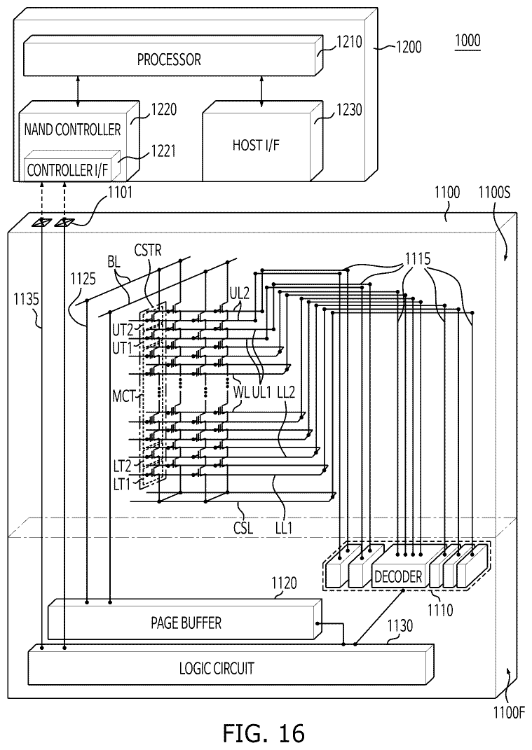

In some example embodiments, the source structures 102 and 104 may be formed on the cell substrate 100. The source structures 102 and 104 may be disposed between the cell substrate 100 and the first mold structure MS1. For example, the source structures 102 and 104 may extend along an upper surface of the cell substrate 100. The source structures 102 and 104 may be formed to be connected to the channel layer 140 of the channel structure CH. The source structures 102 and 104 may be used as a common source line (e.g., CSL of FIG. 16) of the semiconductor memory device. For example, the source structures 102 and 104 may include doped or undoped polysilicon and/or metal doped with an impurity, but example embodiments are not limited thereto.

In some example embodiments, the channel structure CH may be formed through the source structures 102 and 104. For example, a lower portion of the channel structure CH may be formed through the source structures 102 and 104 and disposed in the cell substrate 100.

In some example embodiments, the source structure 102 and 104 may include multiple films. For example, the source structures 102 and 104 may include a first source layer 102 and a second source layer 104 which are sequentially stacked on the cell substrate 100. Each of the first source layer 102 and the second source layer 104 may include polysilicon doped with an impurity or polysilicon undoped with an impurity, but example embodiments are not limited thereto. The first source layer 102 may be in contact with the channel layer 140 and provided as a common source line (e.g., CSL of FIG. 16) of the semiconductor memory device. The second source layer 104 may be used as a support layer for preventing the mold stack from collapsing or falling in a replacement process for forming the first source layer 102.

Although not illustrated, a base insulating layer may be interposed between the cell substrate 100 and the source structures 102 and 104. For example, the base insulating film may include at least one of silicon oxide, silicon nitride, and silicon oxynitride, but is not limited thereto.

In some example embodiments, the source structures 102 and 104 may not be formed in the extension region EXT where an insulating substrate 101 is formed. An upper surface of the insulating substrate 101 is disposed coplanar with the upper surface of the source structure 102 and 104, but this is merely an example. As another example, the upper surface of the insulating substrate 101 may be higher than the upper surfaces of the source structures 102 and 104.

In some example embodiments, a source sacrificial film 103 may be formed on a portion of the cell substrate 100. For example, the source sacrificial film 103 may be formed on a portion of the cell substrate 100 in the extension region EXT. The source sacrificial film 103 may include a material having etch selectivity with respect to the mold insulating layers 110 and 115. For example, the mold insulating layers 110 and 115 may include silicon oxide and may or may not include silicon nitride, and the source sacrificial film 103 may include silicon nitride and may or may not include silicon oxide. The source sacrificial film 103 may be a layer that remains after a portion of the source structure 102 and 104 has been replaced with the source layer 102 in the manufacturing process.

The block isolation pattern WC may extend in the first direction D1 to cut the mold structures MS1 and MS2. At least a portion of the block isolation pattern WC may completely cut through the mold structures MS1 and MS2. At least a portion of the block isolation pattern WC may partially cut the mold structures MS1 and MS2.

A string isolation structure SC may extend in the first direction D1 to cut the string select line. For example, the string isolation structure SC formed in the cell block BLK may cut the string select line. The divided string select lines may independently control each region.

The string isolation structure SC may include an insulating material, for example, at least one of silicon oxide, silicon nitride, and silicon oxynitride, but example embodiments are not limited thereto.

The bit line BL may be formed on the mold structures MS1 and MS2. The bit line BL may extend in the second direction D2 and intersect the block isolation pattern WC. In some example embodiments, the bit line BL may extend in the second direction D2 and be connected to the plurality of channel structures CH arranged along the second direction D2. For example, the bit line contact 174 connected to an upper portion of each of the channel structures CH may be formed in a second interlayer insulating film 194. The bit line BL may be electrically connected to the channel structures CH through the bit line contact 174.

The word line contact 172 may be connected to each of the gate electrodes 120 and 125. For example, the word line contacts 172 may extend in the third direction D3 within interlayer insulating films 192 and 194 and be connected to the gate electrodes 120 and 125, respectively. In some example embodiments, the word line contact 172 may have a bent portion between the first mold structure MS1 and the second mold structure MS2.

The source contact 176 may be connected to the source structures 102 and 104. For example, the source contact 176 may extend in the third direction D3 within the interlayer insulating films 192 and 194 and be connected to the cell substrate 100. In some example embodiments, the source contact 176 may have a bent portion between the first mold structure MS1 and the second mold structure MS2.

In some example embodiments, the mold structures MS1 and MS2 of the through region THR may include a plurality of mold sacrificial films 112 and 117 and the plurality of mold insulating layers 110 and 115 alternately stacked on the cell substrate 100 and/or on the insulating substrate 101. Each of the mold sacrificial films 112 and 117 and each of the mold insulating layers 110 and 115 may have a layered structure extending parallel to the upper surface of the cell substrate 100. The mold sacrificial films 112 and 117 may be spaced apart from each other by the mold insulating layers 110 and 115 and sequentially stacked on the cell substrate 100.

In some example embodiments, the first mold structure MS1 of the through region THR may include the plurality of first mold sacrificial films 112 and the plurality of first mold insulating layers 110 alternately stacked on the cell substrate 100, and the second mold structure MS2 of the through region THR may include the plurality of second mold sacrificial films 117 and the plurality of second mold insulating layers 115 alternately stacked on the first mold structure MS1.

For example, the mold sacrificial films 112 and 117 may include an insulating material, for example, at least one of silicon oxide, silicon nitride, and silicon oxynitride, but is not limited thereto. In some example embodiments, the mold sacrificial films 112 and 117 may include a material having etch selectivity with respect to the mold insulating layers 110 and 115. For example, the mold insulating layers 110 and 115 may include silicon oxide, and the mold sacrificial films 112 and 117 may include silicon nitride.

The interlayer insulating films 192 and 194 may be formed on the cell substrate 100 and cover the mold structures MS1 and MS2. In some example embodiments, the interlayer insulating films 192 and 194 may include the first interlayer insulating film 192 and the second interlayer insulating film 194 that are sequentially stacked on the cell substrate 100. The first interlayer insulating film 192 may cover the first mold structure MS1, and the second interlayer insulating film 194 may cover the second mold structure MS2. For example, the interlayer insulating films 192 and 194 may include at least one of silicon oxide, silicon oxynitride, and a low-k material having a dielectric constant lower than that of silicon oxide, and may or may not include the same material, but is not limited thereto.

The through via 182 may be disposed in the through region THR. For example, the through via 182 may extend in the mold structures MS1 and MS2 of the through region THR in the third direction D3. In some example embodiments, the through via 182 may include a bent portion between the first mold structure MS1 and the second mold structure MS2. Although the through via 182 formed through the mold structures MS1 and MS2 is illustrated, this is merely an example. As another example, the through via 182 may be disposed outside the mold structures MS1 and MS2, in which case the through via 182 may not be formed through the mold structures MS1 and MS2.

The word line contact 172, the source contact 176, and the through via 182 may be connected to the first wiring structure 180 on the interlayer insulating films 192 and 194, respectively. For example, a wiring insulating film 196 may be formed on the second interlayer insulating film 194. The first wiring structure 180 may be formed in the wiring insulating film 196. The word line contact 172, the source contact 176 and the through via 182 may each be connected to the first wiring structure 180 by a contact via 184. Although not illustrated in detail, the first wiring structure 180 may be connected to the bit line BL.

In some example embodiments, the support structure 178 may be formed in the mold structures MS1 and MS2 of the extension region EXT. The support structure 178 may be formed in a shape similar to that of the channel structure CH to reduce stress applied to the mold structures MS1 and MS2 in the extension region EXT.

The peripheral circuit region PERI may include a peripheral circuit substrate 300, a peripheral circuit element 360, and a peripheral circuit wiring structure 380.

The peripheral circuit substrate 300 may be disposed under the cell substrate 100. For example, an upper surface of the peripheral circuit substrate 300 may be opposite the second side 100_B of the cell substrate 100. For example, the peripheral circuit substrate 300 may include a semiconductor substrate such as a silicon substrate, a germanium substrate, a silicon-germanium substrate, etc. Alternatively or additionally, the peripheral circuit substrate 300 may also include a silicon-on-insulator (SOI) substrate, a germanium-on-insulator (GOI) substrate, etc.

The peripheral circuit element 360 may be formed on the peripheral circuit substrate 300. The peripheral circuit element 360 may configure a peripheral circuit that controls the operation of the semiconductor memory device. For example, the peripheral circuit element 360 may include a logic circuit 1130, a page buffer 1120, a decoder 1110, etc. of FIG. 16. In the following description, the surface of the peripheral circuit substrate 300 where the peripheral circuit element 360 is disposed may be referred to as a front side of the peripheral circuit substrate 300. Conversely, the surface of the peripheral circuit substrate 300 opposite the front side of the peripheral circuit substrate 300 may be referred to as a back side of the peripheral circuit substrate 300.

For example, the peripheral circuit element 360 may include a transistor, but example embodiments are not limited thereto. For example, the peripheral circuit element 360 may include not only various active elements such as transistors such as planar and/or three-dimensional transistors, etc., but also various passive elements such as capacitors, resistors, inductors, etc.

The peripheral circuit wiring structure 380 may be formed on the peripheral circuit element 360. For example, a peripheral wiring insulating film 340 may be formed on the front side of the peripheral circuit substrate 300, and the peripheral circuit wiring structure 380 may be formed in the peripheral wiring insulating film 340. The peripheral circuit wiring structure 380 may be electrically connected to the peripheral circuit element 360. The number, arrangement, etc. of the layers of the peripheral circuit wiring structure 380 illustrated herein are merely examples, and example embodiments are not limited thereto.

FIG. 5 is a diagram provided to explain a semiconductor memory device according to some example embodiments. FIG. 6 is a cross-sectional view taken along line CL2 of FIG. 5. For reference, FIG. 5 may correspond to an enlarged view of the region Q1 of FIG. 2. The semiconductor memory device of FIGS. 5 and 6 may be substantially the same as the semiconductor memory device described above with reference to FIGS. 3 and 4, except that the ion storage layer 132 is not included. For convenience of description, different configurations from those described above with reference to FIGS. 1 to 4 will be mainly described.

Referring to FIG. 5, in semiconductor memory device according to some example embodiments, the channel structure CH may include the ion conductive layer 134, the channel layer 140, and the filling insulating layer FI.

The ion conductive layer 134 may be disposed between the first gate electrode 120 and the channel layer 140. For example, the inner surface of the ion conductive layer 134 may be in contact with the outer surface of the channel layer 140, and the outer surface of the ion conductive layer 134 may be in contact with the first gate electrode 120. Referring to FIG. 6, the ion conductive layer 134 may have a shape of a hollow tube (e.g., a cylindrical shape) and may surround the channel layer 140. In addition, the ion conductive layer 134 may be surrounded by the first gate electrode 120.

In some example embodiments, the active ions stored in the first gate electrode 120 may include metal ions. For example, the first gate electrode 120 may include a metal ion storage material, and the first gate electrode 120 may serve as an ion storage layer. For example, the first gate electrode 120 may include at least one of a metal such as Cu or Ag, or a metal oxide such as CuOx, but is not limited thereto. The first gate electrode 120 may be in direct contact with the ion conductive layer 134. Therefore, the active ions stored in the first gate electrode 120 may move to the channel layer 140 through the ion conductive layer 134. Alternatively or additionally, the active ions moved to the channel layer 140 may move again to the first gate electrode 120 through the ion conductive layer 134.

The ion conductive layer 134 may include an electrolyte through which metal ions may be movable between the first gate electrode 120 and the channel layer 140. For example, the ion conductive layer 134 may include a metal oxide such as HfOx (HfO2), but is not limited thereto.

The channel layer 140 may include a material that changes in conductivity with metal ions moving from the first gate electrode 120 through a partial region of the ion conductive layer 134. For example, the ion conductive layer 134 may include a metal oxide such as WOx, but is not limited thereto.

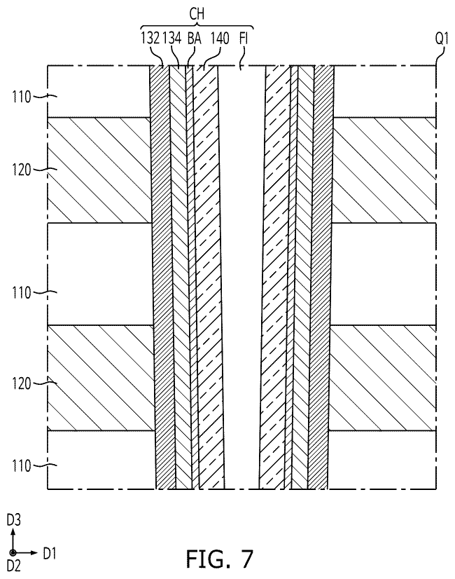

FIG. 7 is a diagram provided to explain a semiconductor memory device according to some example embodiments. For reference, FIG. 7 may correspond to an enlarged view of the region Q1 of FIG. 2. The semiconductor memory device of FIG. 7 may be substantially the same as the semiconductor memory device described above with reference to FIGS. 3 and 4, except that a barrier layer BA is further included. For convenience of description, different configurations from those described above with reference to FIGS. 1 to 4 will be mainly described.

Referring to FIG. 7, the channel structure CH may include the ion storage layer 132, the ion conductive layer 134, the barrier layer BA, the channel layer 140, and the filling insulating layer FI sequentially disposed on the first gate electrode 120.

The barrier layer BA may be disposed inside the channel structure CH, for example, between the ion conductive layer 134 and the channel layer 140 to overcome the issue of interaction between the data retention time and the operating speed. For example, an inner surface of the barrier layer BA may be in contact with the outer surface of the channel layer 140, and an outer surface of the barrier layer BA may be in contact with the ion conductive layer 134. The barrier layer BA may have a shape of a hollow tube (e.g., a cylindrical shape or a tapered cylindrical shape) and may surround the channel layer 140.

The barrier layer BA may include a material for controlling the movement of active ions between the ion storage layer 132 and the channel layer 140. In some example embodiments, the barrier layer BA may include a metal oxide. For example, if the active ion is or includes an oxygen ion, the barrier layer BA may include AlOx, etc. As another example, if the active ion is or includes a lithium ion, the barrier layer BA may include Al2O3, etc. In some example embodiments, the barrier layer BA may include a two-dimensional material. For example, if the active ion is or includes a lithium ion, the barrier layer BA may include graphene, etc. However, the material for the barrier layer BA is not limited to the examples described above, and is not limited to any specific type of active ions.

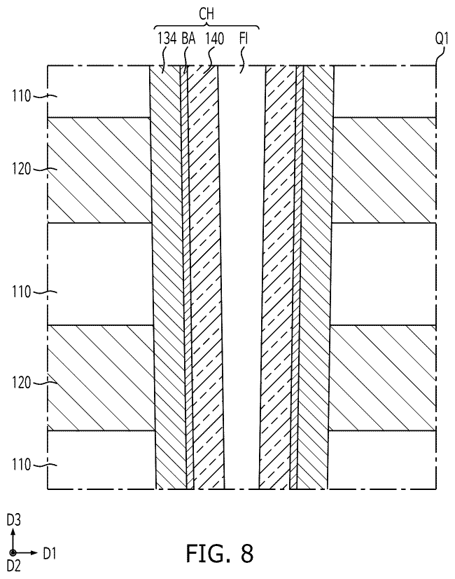

FIG. 8 is a diagram provided to explain a semiconductor memory device according to some example embodiments. For reference, FIG. 8 may correspond to an enlarged view of the region Q1 of FIG. 2. The semiconductor memory device of FIG. 8 may be substantially the same as the semiconductor memory device described above with reference to FIG. 7, except that the ion storage layer 132 is not included. For convenience of description, different configurations from those described above with reference to FIGS. 1 to 7 will be mainly described.

Referring to FIG. 8, the channel structure CH may include the ion conductive layer 134, the barrier layer BA, the channel layer 140, and the filling insulating layer FI sequentially disposed on the first gate electrode 120.

The barrier layer BA may be disposed between the ion conductive layer 134 and the channel layer 140, and may include a material for controlling movement of active ions (e.g., metal ions) between the first gate electrode 120 and the channel layer 140.

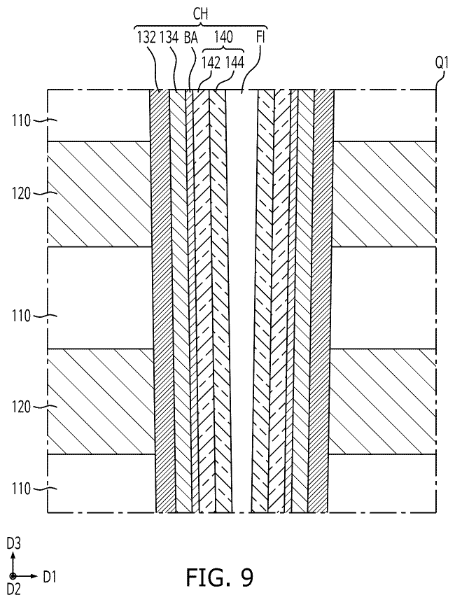

FIG. 9 is a diagram provided to explain a semiconductor memory device according to some example embodiments. For reference, FIG. 9 may correspond to an enlarged view of the region Q1 of FIG. 2. The semiconductor memory device of FIG. 9 may be substantially the same as the semiconductor memory device described above with reference to FIGS. 5 and 6, except that the channel layer 140 includes a first sub pattern 142 and a second sub pattern 144. For convenience of description, different configurations from those described above with reference to FIGS. 1 to 8 will be mainly described.

Referring to FIG. 9, the channel structure CH may include the ion storage layer 132, the ion conductive layer 134, the barrier layer BA, the channel layer 140, and the filling insulating layer FI.

In some example embodiments, the channel layer 140 may include the first sub pattern 142 and the second sub pattern 144. The first sub pattern 142 may be disposed between the second sub pattern 144 and the barrier layer BA. The second sub pattern 144 may be disposed between a first sub pattern SP1 and the filling insulating layer FI. The first sub pattern SP1 may surround the filling insulating layer FI.

The first sub pattern 142 may be a semiconductor pattern including a first conductivity type dopant. For example, the first sub pattern 142 may include single crystal silicon or polycrystalline silicon, and may or may not be doped with an N-type dopant such as at least one of phosphorus or arsenic. alternatively or additionally, the first sub pattern 142 may include an N-type oxide semiconductor such as ZnO, In2O3, SnO2, CdO, Ga2O3, TiO2, etc.

The second sub pattern 144 may be a semiconductor pattern including a dopant of a second conductivity type different from the first conductivity type. For example, the second sub pattern 144 may include single crystal silicon or polycrystalline silicon, and may or may not be doped with a P-type dopant such as boron. For example, the second sub pattern 144 may include a P-type oxide semiconductor such as Cu2O, CuOx, NiO, NiOx, Co3O4, Cr2O3, CuAlO2, SnO, LaCuOSe, SrCu2O2, CuGaO2, ZnRh2O4, etc.

In some example embodiments, the active ions stored in the ion storage layer 132 may move to the first sub pattern 142 through the ion conductive layer 134. In addition, the active ions moved to the first sub pattern 142 may move to the ion storage layer 132 through the ion conductive layer 134.

In the erase mode, a voltage VBL may be applied to the erase target bit line. In this case, a voltage VERS may be applied to the second sub pattern 144 to supply holes to the first sub pattern 142. With such a configuration, efficiency of the bulk erase may be improved.

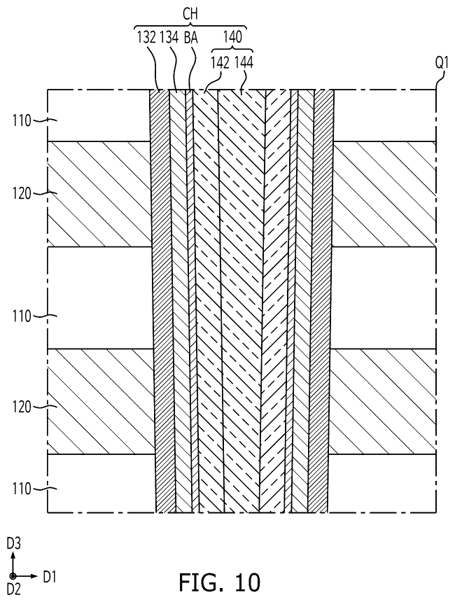

FIG. 9 illustrates an example of the channel structure CH including the barrier layer BA, but unlike this, the channel structure CH may not include the barrier layer BA. In some example embodiments, the channel structure CH may include the ion storage layer 132, the ion conductive layer 134, the first sub pattern 142, the second sub pattern 144, and the filling insulating layer FI sequentially disposed on the first gate electrode 120. In this case, the first sub pattern 142 may be disposed between the ion conductive layer 134 and the second sub pattern 144. For example, an outer surface of the first sub pattern 142 may be in contact with an inner surface of the ion conductive layer 134. An inner surface of the first sub pattern 142 may be in contact with an outer surface of the second sub pattern 144. Unlike the aspect described above, in various aspects of the semiconductor memory device of FIGS. 10 to 14 to be described below, the channel structure CH may not include the barrier layer BA.

FIG. 10 is a diagram provided to explain a semiconductor memory device according to some example embodiments. For reference, FIG. 10 may correspond to an enlarged view of the region Q1 of FIG. 2. The semiconductor memory device of FIG. 10 may be substantially the same as the semiconductor memory device described above with reference to FIG. 9, except that the filling insulating layer FI is not included. For convenience of description, different configurations from those described above with reference to FIGS. 1 to 9 will be mainly described.

Referring to FIG. 10, the channel structure CH may include the ion storage layer 132, the ion conductive layer 134, the barrier layer BA, and the channel layer 140.

In some example embodiments, the channel layer 140 may include the first sub pattern 142 and the second sub pattern 144. The first sub pattern 142 may be disposed between the second sub pattern 144 and the barrier layer BA. The second sub pattern 144 may fill the inside of the first sub pattern SP1.

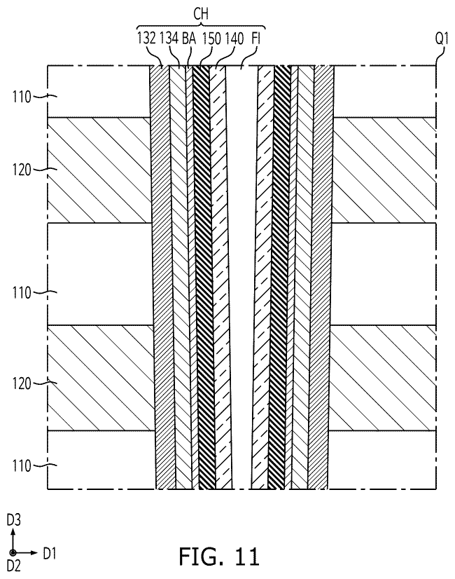

FIG. 11 is a diagram provided to explain a semiconductor memory device according to some example embodiments. For reference, FIG. 11 may correspond to an enlarged view of the region Q1 of FIG. 2. The channel structure CH of the semiconductor memory device of FIG. 11 may be substantially the same as the semiconductor memory device described above with reference to FIG. 7, except that a resistance switching layer 150 disposed between the ion conductive layer 134 and the channel layer 140 is further included. For convenience of description, different configurations from those described above with reference to FIGS. 1 to 10 will be mainly described.

Referring to FIG. 11, the channel structure CH may include the ion storage layer 132, the ion conductive layer 134, the barrier layer BA, the resistance switching layer 150, the channel layer 140, and the filling insulating layer FI.

In some example embodiments, the resistance switching layer 150 may be disposed between the ion conductive layer 134 and the channel layer 140. Specifically, the resistance switching layer 150 may be interposed between the barrier layer BA disposed on the ion conductive layer 134 and the channel layer 140. For example, an outer surface of the resistance switching layer 150 may be in contact with the inner surface of the barrier layer BA, and an inner surface of the resistance switching layer 150 may be in contact with the outer surface of the channel layer 140.

The resistance switching layer 150 may include a material that changes in conductivity with oxygen ions. For example, the resistance switching layer 150 may include a metal oxide such as WOx. However, the material for the resistance switching layer 150 is not limited to the examples described above, and is not limited to any specific type active ions.

In some example embodiments, if a voltage is applied to one gate electrode selected from among the plurality of first gate electrodes 120, the conductivity of the resistance switching layer 150 may change with the active ions moving through a partial region of the ion conductive layer 134 associated with the selected gate electrode. In this case, the active ions stored in the ion storage layer 132 may move to the resistance switching layer 150 through the ion conductive layer 134. alternatively or additionally, the active ions moved to the resistance switching layer 150 may move to the ion storage layer 132 through the ion conductive layer 134.

In the read mode, if a voltage is applied to one gate electrode selected from among the plurality of first gate electrodes 120, a read path may be formed to go through the channel layer 140, the resistance switching layer 150 and the channel layer 140 in order. For example, the read path may bypass from the channel layer 140 to the resistance switching layer 150 in a region adjacent to the selected gate electrode. If a voltage is applied to one gate electrode selected from among the plurality of first gate electrodes 120, the conductivity of the resistance switching layer 150 may change, and the read path may be formed as the active ions of the ion storage layer 132 move to the resistance switching layer 150 instead of the channel layer 140.

Through this, the read operation may be performed through the active ions moving between the first gate electrode 120 and the resistance switching layer 150 to reduce the frequency with which active ions directly penetrate the channel layer 140, thereby delaying the degradation of the channel layer 140 and improving the electrical properties of the semiconductor memory device.

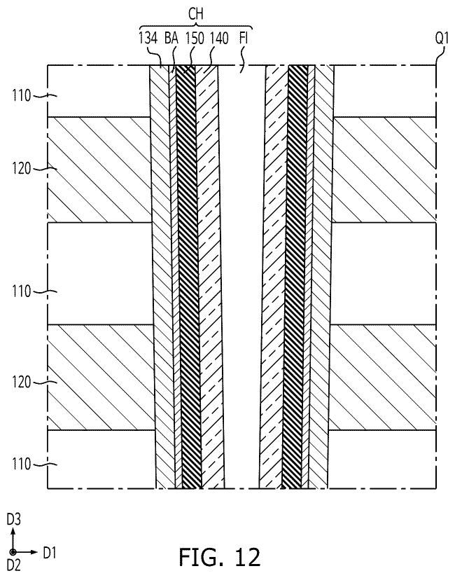

FIG. 12 is a diagram provided to explain a semiconductor memory device according to some example embodiments. For reference, FIG. 12 may correspond to an enlarged view of the region Q1 of FIG. 2. The semiconductor memory device of FIG. 12 may be substantially the same as the semiconductor memory device described above with reference to FIG. 11, except that the ion storage layer 132 is not included. For convenience of description, different configurations from those described above with reference to FIGS. 1 to 11 will be mainly described.

Referring to FIG. 12, the channel structure CH may include the ion conductive layer 134, the barrier layer BA, the resistance switching layer 150, the channel layer 140, and the filling insulating layer FI.

The resistance switching layer 150 may include a material that changes in conductivity with metal ions. For example, the resistance switching layer 150 may include transition-metal oxide (TMO). However, the material for the resistance switching layer 150 is not limited to the examples described above, and is not limited to any specific type of active ions.

In some example embodiments, if a voltage is applied to one gate electrode selected from among the plurality of first gate electrodes 120, the conductivity of the resistance switching layer 150 may be changed by the active ions moving through a partial region of the ion conductive layer 134 associated with the selected gate electrode. In this case, the active ions stored in the first gate electrode 120 may move to the resistance switching layer 150 through the ion conductive layer 134. Alternatively or additionally, the active ions moved to the resistance switching layer 150 may move to the first gate electrode 120 through the ion conductive layer 134.

In the read mode, if a voltage is applied to one gate electrode selected from among the plurality of first gate electrodes 120, a read path that is a bypass may be formed. For example, if a voltage is applied to one gate electrode selected from among the plurality of first gate electrodes 120, a read path may be formed, which goes through the resistance switching layer 150 adjacent to the selected gate electrode at the vertical level where the selected gate electrode is positioned. This read path may be formed as the conductivity of the resistance switching layer 150 is changed by the voltage applied to the selected gate electrode, resulting in the active ions (e.g., metal ions) of the first gate electrode 120 moving to the resistance switching layer 150 instead of the channel layer 140.

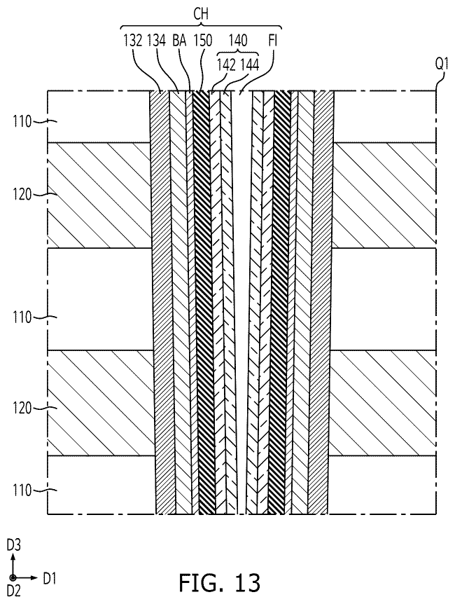

FIG. 13 is a diagram provided to explain a semiconductor memory device according to some example embodiments. For reference, FIG. 13 may correspond to an enlarged view of the region Q1 of FIG. 2. The channel structure CH of the semiconductor memory device of FIG. 13 may be substantially the same as the semiconductor memory device described above with reference to FIG. 9, except that the resistance switching layer 150 disposed between the ion conductive layer 134 and the channel layer 140 is further included. For convenience of description, different configurations from those described above with reference to FIGS. 1 to 12 will be mainly described.

Referring to FIG. 13, the channel structure CH may include the ion storage layer 132, the ion conductive layer 134, the barrier layer BA, the resistance switching layer 150, the channel layer 140, and the filling insulating layer FI.

In some example embodiments, the resistance switching layer 150 may be disposed between the ion conductive layer 134 and the channel layer 140. In detail, the resistance switching layer 150 may be interposed between the barrier layer BA disposed on the ion conductive layer 134 and the channel layer 140. In addition, the channel layer 140 may include the first sub pattern 142 and the second sub pattern 144. For example, the outer surface of the resistance switching layer 150 may be in contact with the inner surface of the barrier layer BA, and the inner surface of the resistance switching layer 150 may be in contact with the outer surface of the first sub pattern 142.

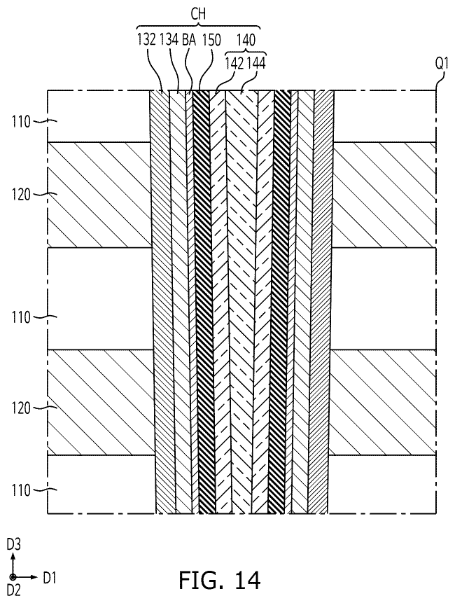

FIG. 14 is a diagram provided to explain a semiconductor memory device according to some example embodiments. For reference, FIG. 14 may correspond to an enlarged view of the region Q1 of FIG. 2. The channel structure CH of the semiconductor memory device of FIG. 14 may be substantially the same as the semiconductor memory device described above with reference to FIG. 13, except that the filling insulating layer FI is not included. For convenience of description, different configurations from those described above with reference to FIGS. 1 to 13 will be mainly described.

Referring to FIG. 14, the channel structure CH may include the ion storage layer 132, the ion conductive layer 134, the barrier layer BA, the resistance switching layer 150, the first sub pattern 142, and the second sub pattern 144 sequentially disposed on the first gate electrode 120. The first sub pattern 142 may be disposed between the second sub pattern 144 and the barrier layer BA. The second sub pattern 144 may fill the inside of the first sub pattern SP1.

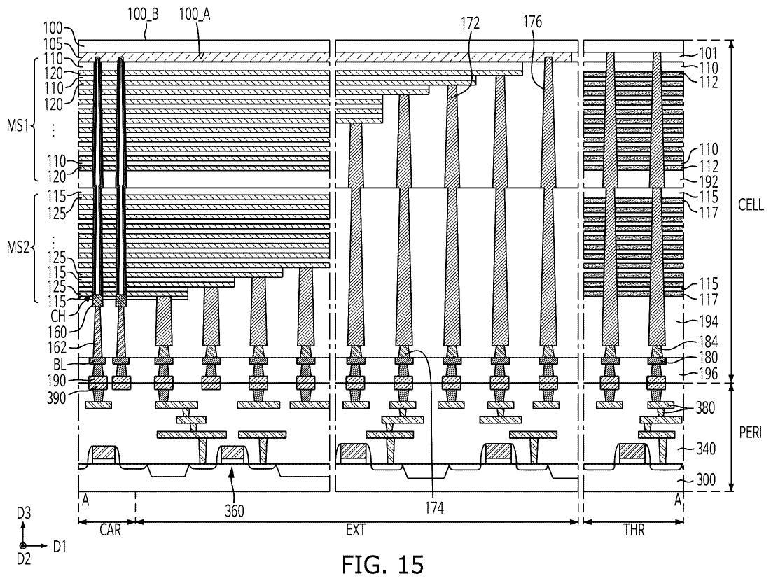

FIG. 15 is a diagram provided to explain a semiconductor memory device according to some example embodiments.

Referring to FIG. 15, the semiconductor memory device according to some example embodiments may include a common source plate 105.

The common source plate 105 may be disposed on the first side 100_A of the cell substrate 100. The common source plate 105 may be connected to the channel structure CH. For example, the common source plate 105 may be electrically connected to the channel layer of the channel structure CH. The common source plate 105 may be used as a common source line (e.g., CSL of FIG. 16) of the semiconductor memory device. The first mold structure MS1 and the second mold structure MS2 may be disposed on (e.g., on a lower portion of) the common source plate 105. For example, the common source plate 105 may include polycrystalline silicon or metal doped with an impurity, but example embodiments are not limited thereto.

The semiconductor memory device according to some example embodiments may have a chip-to-chip (C2C) structure. The C2C structure refers to manufacturing an upper chip including the memory cell region CELL on a first wafer (e.g., the cell substrate 100), manufacturing a lower chip including the peripheral circuit region PERI on a second wafer (e.g., the peripheral circuit substrate 300) that is different from the first wafer, and connecting the upper and lower chips to each other by a bonding method.

For example, the bonding method may refer to a method of electrically connecting a first bonding metal 190 formed on an uppermost metal layer of the upper chip and a second bonding metal 390 formed on an uppermost metal layer of the lower chip to each other. For example, if the first bonding metal 190 and the second bonding metal 390 are formed of copper (Cu), the bonding method may be a Cu-Cu bonding method. However, this is only an example, and first bonding metal 190 and the second bonding metal 390 may be formed of various other metals such as aluminum (Al) and/or tungsten (W).

As the first bonding metal 190 and the second bonding metal 390 are bonded to each other, the first wiring structure 180 may be connected to a second wiring structure 380. Accordingly, the bit line BL and each of the gate electrodes 120 and 125 may be electrically connected to the peripheral circuit element 360.

FIG. 16 is a block diagram provided as an example to explain an electronic system according to some example embodiments.

Referring to FIG. 16, an electronic system 1000 may include a semiconductor memory device 1100 described above with reference to FIGS. 1 to 15, and a controller 1200 electrically connected to the semiconductor memory device 1100. The electronic system 1000 may be a storage device including one or a plurality of semiconductor memory devices 1100 or an electronic device including the storage device. For example, the electronic system 1000 may be or may include (or be included in) one or more of a solid state drive device (SSD), a universal serial bus (USB), a computing system, a medical device, or a communication device, which may include one or the plurality of semiconductor memory devices 1100.

For example, the semiconductor memory device 1100 may be the NAND flash memory device described above with reference to FIGS. 1 to 15. The semiconductor memory device 1100 may include a first structure 1100F and a second structure 1100S on the first structure 1100F. The first structure 1100F may be a peripheral circuit structure including a decoder circuit 1110, the page buffer 1120, and the logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL and upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may vary according to various aspects.

In some example embodiments, the upper transistors UT1 and UT2 may include a string select transistor, and the lower transistors LT1 and LT2 may include a ground select transistor. The gate lower lines LL1 and LL2 each may be gate electrodes of the lower transistors LT1 and LT2. The word lines WL may be gate electrodes of the memory cell transistors MCT, and the gate upper lines UL1 and UL2 may be gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 through first connection lines 1115 extending from within the first structure 1100F and to the second structure 1100S. The bit lines BL may be electrically connected to the page buffer 1120 through second connection wires 1125 extending from within the first structure 1100F and to the second structure 1100S.

In the first structure 1100F, the decoder circuit 1110 and the page buffer 1120 may perform a control operation on at least one memory cell transistor selected from among the plurality of memory cell transistors MCT. The decoder circuit 1110 and the page buffer 1120 may be controlled by the logic circuit 1130. The semiconductor memory device 1100 may communicate with the controller 1200 through the input and output pad 1101 electrically connected to the logic circuit 1130. The input and output pad 1101 may be electrically connected to the logic circuit 1130 through an input and output connection wiring 1135 extending from within the first structure 1100F and to the second structure 1100S.

The controller 1200 may include a processor 1210, a NAND controller 1220, and a host interface 1230. According to some example embodiments, the electronic system 1000 may include the plurality of semiconductor memory devices 1100, and in this case, the controller 1200 may control the plurality of semiconductor memory devices 1100.

The processor 1210 may control the overall operation of the electronic system 1000 including the controller 1200. The processor 1210 may operate according to predetermined firmware, and may control the NAND controller 1220 to access the semiconductor memory device 1100. The NAND controller 1220 may include a NAND interface (or controller interface) 1221 that processes communication with the semiconductor memory device 1100. A control command for controlling the semiconductor memory device 1100, data to be written in the memory cell transistors MCT of the semiconductor memory device 1100, data to be read from the memory cell transistors MCT of the semiconductor memory device 1100, etc., may be transmitted through the NAND interface 1221. The host interface 1230 may provide a function of communication between the electronic system 1000 and an external host. Upon receiving a control command from the external host through the host interface 1230, the processor 1210 may control the semiconductor memory device 1100 in response to the control command.

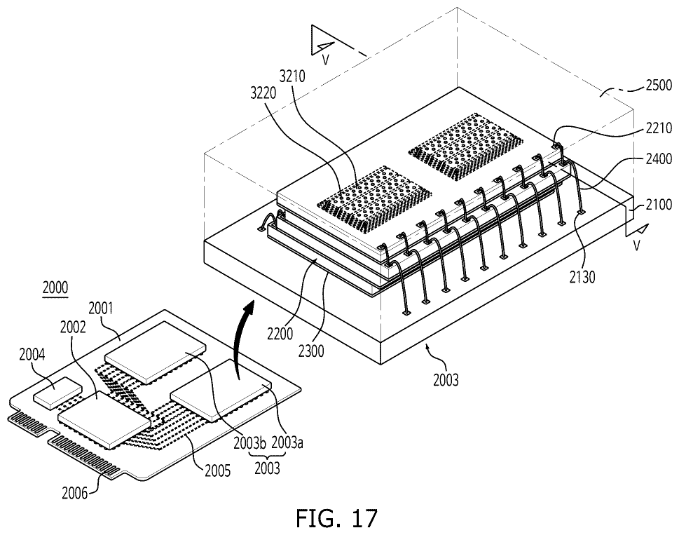

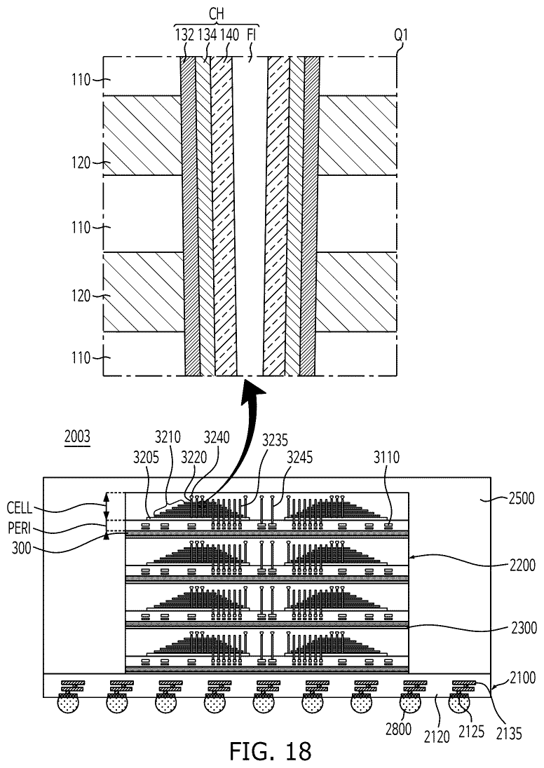

FIG. 17 is an example perspective view illustrating an electronic system 2000 including a semiconductor memory device according to some example embodiments. FIG. 18 is a schematic cross-sectional view taken along line V-V of FIG. 17.

Referring to FIG. 17, the electronic system 2000 may include a main substrate 2001, a controller 2002 mounted on the main substrate 2001, one or more semiconductor packages 2003, and a DRAM 2004. The semiconductor package 2003 and the DRAM 2004 may be connected to the controller 2002 by wiring patterns 2005 formed on the main substrate 2001.

The main substrate 2001 may include a connector 2006 including a plurality of pins coupled to the external host. The number and arrangement of the plurality of pins in the connector 2006 may vary according to a communication interface between the electronic system 2000 and the external host. In some example embodiments, the electronic system 2000 may communicate with an external host according to any one or more of interfaces such as Universal Serial Bus (USB), Peripheral Component Interconnect Express (PCI-Express), Serial Advanced Technology Attachment (SATA), and M-Phy for Universal Flash Storage (UFS). In some example embodiments, the electronic system 2000 may operate by the power supplied from an external host through the connector 2006. The electronic system 2000 may further include a Power Management Integrated Circuit (PMIC) that distributes the power supplied from the external host to the controller 2002 and the semiconductor package 2003.

The main controller 2002 may record data in the semiconductor package 2003 or read data from the semiconductor package 2003, and may improve the operation speed of the electronic system 2000.

The DRAM 2004 may be a buffer memory to alleviate the speed difference between the external host and the semiconductor package 2003 that is a data storage space. The DRAM 2004 included in the electronic system 2000 may also operate as a kind of cache memory, and may also provide a space for temporarily storing data in a control operation for the semiconductor package 2003. If the electronic system 2000 includes the DRAM 2004, in addition to the NAND controller for controlling the semiconductor package 2003, the main controller 2002 may further include a DRAM controller for controlling the DRAM 2004.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on a lower surface of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100. The package substrate 2100 may be a printed circuit substrate including package upper pads 2130. Each of the semiconductor chips 2200 may include an input and output pad 2210. The input and output pad 2210 may correspond to the input and output pad 1101 of FIG. 16. Each of the semiconductor chips 2200 may include metal lines 3210 and channel structures 3220. Each of the semiconductor chips 2200 may include the semiconductor memory device described above with reference to FIGS. 1 to 15.

In some example embodiments, the connection structure 2400 may be a bonding wire electrically connecting the input and output pad 2210 to the package upper pads 2130. Accordingly, in each of the first and second semiconductor packages 2003a and 2003b, the semiconductor chips 2200 may be electrically connected to each other with the bonding wire method, and may be electrically connected to the package upper pads 2130 of the package substrate 2100. In some example embodiments, in each of the first and second semiconductor packages 2003a and 2003b, the semiconductor chips 2200 may be electrically connected to each other through a connection structure including through-electrodes (Through Silicon Via, TSV) instead of the bonding wire type connection structure 2400.

In some example embodiments, the main controller 2002 and the semiconductor chips 2200 may be included in one package. In some example embodiments, the main controller 2002 and the semiconductor chips 2200 may be mounted on a separate interposer substrate different from the main substrate 2001, and the main controller 2002 and the semiconductor chips 2200 may be connected to each other through wiring formed on the interposer substrate.

In some example embodiments, the package substrate 2100 may be a printed circuit board. The package substrate 2100 may include a package substrate body portion 2120, the package upper pads 2130 disposed on the upper surface of the package substrate body portion 2120, lower pads 2125 disposed on the lower surface of the package substrate body portion 2120 or exposed through the lower surface, and internal wires 2135 electrically connecting the upper pads 2130 and the lower pads 2125 inside the package substrate body portion 2120. The upper pads 2130 may be electrically connected to the connection structures 2400. The lower pads 2125 may be connected to the wiring patterns 2005 of the main substrate 2001 of the electronic system 2000 through conductive connections 2800, as illustrated in FIG. 17.

In an electronic system according to some example embodiments, each of the semiconductor chips 2200 may include the semiconductor memory device described above with reference to FIGS. 1 to 15. For example, each of the semiconductor chips 2200 may include the peripheral circuit structure PERI and the cell structure CELL stacked on the peripheral circuit structure PERI. For example, the peripheral circuit structure PERI may include the peripheral circuit substrate 300 described above with reference to FIGS. 1 to 15 and a peripheral wiring 3110. In addition, for example, the cell structure CELL may include a common source line 3205, a gate stack structure 3210 on the common source line 3205, a channel structure 3220 and an isolation structure 3230 formed through the gate stack structure 3210, a bit line 3240 electrically connected to the channel structure 3220, and a gate connection wiring electrically connected to the word line of the gate stack structure 3210.

Each of the semiconductor chips 2200 may include a through wiring 3245 electrically connected to the peripheral wiring 3110 of the peripheral circuit structure PERI and extending into the cell structure CELL. The through wiring 3245 may be formed through the gate stack structure 3210 and may be further disposed outside the gate stack structure 3210. Each of the semiconductor chips 2200 may further include an input and output connection wiring 3265 electrically connected to the peripheral wiring 3110 of the peripheral circuit structure PERI and extending into a second structure 3200, and the input and output pad 2210 electrically connected to the input and output connection wiring 3265.

Although certain aspects of inventive concepts have been described with reference to the accompanying drawings, those of ordinary skill in the art to which the present disclosure pertains will understand that some example embodiments may be implemented in other specific forms without changing its technical idea or essential features. Therefore, it should be understood that the aspects described above are illustrative and non-limiting in all respects.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

Although some example embodiments has been described above by way of certain aspects and drawings, example embodiments are not limited thereto, and various changes and modifications can be made within the equivalent scope of the technical idea of the present disclosure and the claims to be described below by those of ordinary skill in the art. Additionally, example embodiments are not necessarily mutually exclusive with one another. For example, some example embodiments may include one or more features described with reference to one or more figures, and may also include one or more other features described with reference to one or more other figures.

1. A semiconductor memory device, comprising:
a substrate;
a mold structure including a plurality of mold insulating layers and a plurality of gate electrodes alternately stacked on the substrate in a first direction; and
a channel structure through the mold structure and extending in the first direction, wherein,
the channel structure comprises a channel layer and an ion conductive layer, the ion conductive layer between the plurality of gate electrodes and the channel layer.

2. The semiconductor memory device according to claim 1, wherein the channel structure further comprises an ion storage layer between the plurality of gate electrodes and the ion conductive layer.

3. The semiconductor memory device according to claim 1, wherein the channel structure further comprises a resistance switching layer between the ion conductive layer and the channel layer.

4. The semiconductor memory device according to claim 1, wherein the channel structure further comprises an ion storage layer between the plurality of gate electrodes and the ion conductive layer, and a resistance switching layer between the ion conductive layer and the channel layer.

5. The semiconductor memory device according to claim 1, wherein the channel structure further comprises a barrier layer between the ion conductive layer and the channel layer.

6. The semiconductor memory device according to claim 1, wherein
the channel layer comprises a first sub pattern and a second sub pattern,
the first sub pattern includes a semiconductor pattern including a dopant of a first conductivity type, and
the second sub pattern includes a semiconductor pattern comprising a dopant of a second conductivity type different from the first conductivity type.

7. The semiconductor memory device according to claim 6, wherein the first sub pattern is between the ion conductive layer and the second sub pattern.

8. The semiconductor memory device according to claim 1, wherein the channel structure further comprises a filling insulating layer on the channel layer.

9. The semiconductor memory device according to claim 2, wherein
the ion storage layer comprises an oxygen ion storage material, and
the oxygen ion storage material comprises at least one of a metal oxide, a transition metal oxide, and a metal-insulator transition material.

10. The semiconductor memory device according to claim 2, wherein
the ion storage layer comprises a lithium ion storage material, and
the lithium ion storage material comprises at least one of crystalline silicon, amorphous silicon, and lithium ion oxide.

11. The semiconductor memory device according to claim 2, wherein
the ion storage layer comprises a hydrogen ion storage material, and
the hydrogen ion storage material comprises at least one of a metal, a metal-based catalyst, silicon, or a conductive polymer.

12. The semiconductor memory device according to claim 1, wherein
the plurality of gate electrodes comprise a metal ion storage material, and
the plurality of gate electrodes are in direct contact with the ion conductive layer.

13. The semiconductor memory device according to claim 3, wherein the resistance switching layer comprises at least one of a metal oxide or a transition metal oxide.

14. The semiconductor memory device according to claim 5, wherein the barrier layer comprises at least one of a metal oxide or a two-dimensional material.

15. The semiconductor memory device according to claim 1, wherein, in response to a voltage applied to one gate electrode selected from among the plurality of gate electrodes, a conductivity of the channel layer changes with active ions moving through a partial region of the ion conductive layer associated with the selected gate electrode.

16. The semiconductor memory device according to claim 3, wherein, in response to a voltage applied to one gate electrode selected from among the plurality of gate electrodes, a conductivity of the resistance switching layer changes with active ions moving through a partial region of the ion conductive layer associated with the selected gate electrode.

17. A semiconductor memory device, comprising:
a substrate;
a mold structure comprising a plurality of mold insulating layers and a plurality of gate electrodes alternately stacked on the substrate in a first direction; and
a channel structure through the mold structure and extending in the first direction, wherein
the channel structure comprises an ion storage layer, an ion conductive layer, a barrier layer, and a channel layer sequentially arranged on the plurality of gate electrodes.

18. The semiconductor memory device according to claim 17, wherein the channel structure further comprises a resistance switching layer between the ion conductive layer and the channel layer.

19. The semiconductor memory device according to claim 17, wherein
the channel layer comprises a first sub pattern and a second sub pattern sequentially disposed on the barrier layer,
the first sub pattern includes a semiconductor pattern including a dopant of a first conductivity type, and
the second sub pattern includes a semiconductor pattern comprising a dopant of a second conductivity type different from the first conductivity type.

20. An electronic system, comprising:
a main substrate;
a semiconductor memory device on the main substrate, comprising a peripheral circuit structure and a cell structure stacked on the peripheral circuit structure; and
a controller on the main substrate, which is electrically connected to the semiconductor memory device, wherein
the cell structure comprises:
a mold structure comprising a plurality of mold insulating layers and a plurality of gate electrodes alternately stacked on the substrate in a first direction; and
a channel structure through the mold structure and extending in the first direction, and
the channel structure comprises a channel layer, and an ion conductive layer between the plurality of gate electrodes and the channel layer.
